(19) United States
(12) Patent Application Publication
(10) Pub. No.: US 2015/0282299 A1
(43) Pub. Date: Oct. 1, 2015

(54) THIN PROFILE METAL TRACE TO SUPPRESS SKIN EFFECT AND EXTEND PACKAGE INTERCONNECT BANDWIDTH

(71) Applicant: XILINX, INC., San Jose, CA (US)

(72) Inventors: Hong Shi, Fremont, CA (US); Paul Y. Wu, Saratoga, CA (US); Jian Tu, Cupertino, CA (US)

(73) Assignee: XILINX, INC., San Jose, CA (US)

(21) Appl. No.: 14/242,795

(22) Filed: Apr. 1, 2014

(51) Int. Cl. H05K 1/02

(52) U.S. Cl. CPC H05K 1/0242

(57) ABSTRACT

Embodiments of the invention generally provide an electronic device comprising an electrical interconnect component that includes an electrical trace. The electrical trace has geometric characteristics that serve to suppress the skin effect over a large band of frequency components. More specifically, the electrical trace has a thickness that is less than a skin depth for a particular chosen frequency component. By making the electrical trace have a thickness that is less than the skin depth, the current flows through substantially the entire cross-sectional area of the electrical trace for all frequencies up to the chosen frequency component, which reduces the effects associated with the skin effect.

### BACKGROUND OF THE INVENTION

1. Field of the Invention

Embodiments of the present invention generally relate to an electrical interconnect component, and in particular, to an electrical interconnect component including an electrical trace having a construction for suppressing a skin effect, thereby increasing bandwidth.

2. Description of the Related Art

Electronic devices, such as tablets, computers, copiers, digital cameras, smart phones, control systems and automated teller machines, among others, often employ electronic components such as dies that are connected by various interconnect components. The dies may include memory, logic or other IC device.

In general, interconnect components are subject to various electrical effects that cause issues such as distortion and attenuation. One such electrical effect is known as a skin effect. The skin effect is a frequency-dependent attenuation effect that affects higher frequency components to a greater degree than lower frequency components. More specifically, current at a higher frequency flows through a narrower portion of the interconnect component than current at a lower frequency, thus reducing the effective cross-sectional area, and thereby increasing the resistance experienced. The skin effect also induces a frequency dependent phase delay into signals, which undesirably causes dispersion.

Therefore, a need exists for an improved interconnect component construction that reduces frequency-dependent effects related to the skin effect.

### SUMMARY OF THE INVENTION

A method and apparatus are provided for suppressing the skin effect in an electrical trace. Advantageously, the construction of the electrical trace suppresses effects in the electrical trace that are related to the skin effect. The effects include frequency-dependent attenuation and frequency-dependent phase delay effects. The improvements described herein generally improve bandwidth, and reduces dispersion, jitter, and bit error.

In one embodiment, an electrical interconnect component of an electronic device is provided. The electronic device has a characteristic data rate. The interconnect component includes a dielectric surface and an electrical trace disposed on the dielectric surface. The electrical trace has a thickness selected in response to the characteristic data rate and independent of any relationship to a width of the electrical trace.

In another embodiment, an electronic device having a characteristic data rate is provided. The electronic device includes an electrical interconnect component. The interconnect component includes a dielectric surface and an electrical trace disposed on the dielectric surface. The electrical trace has a thickness selected in response to the characteristic data rate and independent of any relationship to a width of the electrical trace.

In another embodiment, a method of communicating via an electrical trace is provided. The method includes transmitting a signal having a characteristic data rate through the electrical trace. The electrical trace has a thickness selected in response to the characteristic data rate, the thickness selected independent of any relationship to a width of the electrical trace.

In another embodiment, a method of selecting a thickness for an electrical trace is provided. The method includes determining a characteristic data rate. The method also includes determining a frequency based on the characteristic data rate. The method further includes determining a skin depth based on the frequency. The method further includes determining a thickness for the electrical trace based on the skin depth.

Other features will be recognized from consideration of the Detailed Description and Claims, which follow.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a front schematic view of an electronic device having an integrated chip package including a plurality of integrated circuit dies.

FIG. 2 is a partial cross-sectional view of the package illustrated in FIG. 1.

FIGS. 3A-3D are illustrations of an electrical trace that demonstrate the skin effect.

FIGS. 4A and 4B are graphs that illustrate the effects on attenuation (FIG. 4A) and phase delay (FIG. 4B) caused by the skin effect.

FIGS. 5A-5C are cross-sectional illustrations of electrical traces having a construction for suppressing the skin effect.

FIGS. 6A-6B are graphs illustrating benefits of an electrical trace having a thickness that is dependent on a characteristic data rate.

FIG. 7A is a graph of frequency in GHz versus attenuation in decibels for three electrical traces having different thicknesses.

FIG. 7B is a graph of frequency in Hz versus phase delay in seconds for three electrical traces having different thicknesses.

FIGS. 8A-8B are eye diagrams illustrating data-dependent jitter for electrical traces having different thicknesses.

FIG. 9 is a flow diagram of method steps for determining geometrical characteristics for an electrical trace.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Embodiments of the invention generally provide an electronic device comprising an electrical interconnect component that includes an electrical trace. The electrical trace has geometric characteristics that serve to suppress the skin effect over a large band of frequency components. More specifically, the electrical trace has a thickness that is less than a skin depth for a particular chosen frequency component. By making the electrical trace have a thickness that is less than the skin depth, the current flows through substantially the entire cross-sectional area of the electrical trace for all frequencies up to the chosen frequency component, which reduces the effects associated with the skin effect.

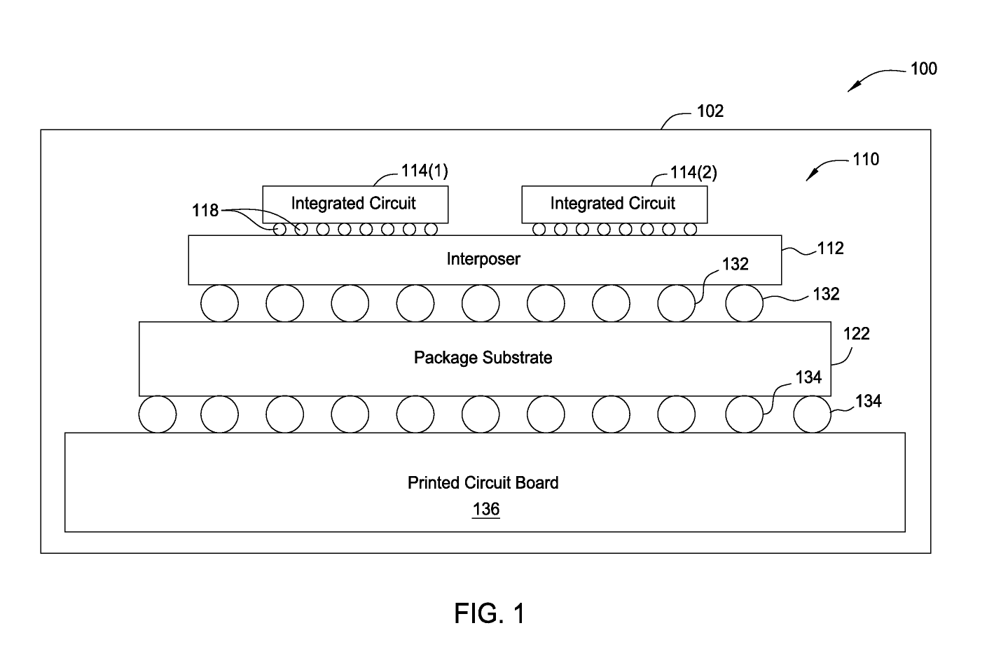

Turning now to FIG. 1, an exemplary electronic device 100 is schematically illustrated. The electronic device 100 includes an integrated chip package 110. The electronic device 100 may be a computer, tablet, cell phone, smart phone, consumer appliance, control system, automated teller machine, programmable logic controller, printer, copier, digital camera, television, monitor, stereo, radio, radar, or other device utilizing and having a chip package 110 disposed therein.

The chip package 110 includes a plurality of IC dies 114 connected optionally by a silicon-through-via (TSV) interposer 112 to a package substrate 122. The chip package 110 may also have an overmold covering the IC dies 114. The interposer 112 includes circuitry for electrically connecting the dies 114 to circuitry of the package substrate 122. The circuitry of the interposer 112 may optionally include transistors. Package bumps 132, also known as “C4 bumps,” are utilized to provide an electrical connection between the circuitry of the interposer 112 and the circuitry of the package substrate 122. The package substrate 122 may be mounted and connected to a printed circuit board (PCB) 136, utilizing solder balls 134, wire bonding or other suitable technique. The PCB 136 is mounted in the interior of a housing 102 of the electronic device 100.

The IC dies 114 are mounted to one or more surfaces of the interposer 112, or alternatively, to the package substrate 122. The IC dies 114 may be programmable logic devices, such as field programmable gate arrays (FPGA), memory devices, optical devices, processors or other IC logic structures. Optical devices include photo-detectors, lasers, optical sources, and the like. In the embodiment depicted in FIG. 1, the IC dies 114 are mounted to a top surface of the interposer 112 by a plurality of micro-bumps 118. The micro-bumps 118 electrically connect the circuitry of each IC die 114 to circuitry of the interposer 112. The circuitry of the interposer 112 connects the micro-bumps 118 to selective package bumps 132, and hence, connects selective circuitry of each IC dies 114 to the package substrate 122, to enable communication of the dies 114 with the PCB after the chip package 110 is mounted within the within the electronic device 100. When the optional interposer 112 is not present, the micro-bumps 118 connect selective circuitry of each IC die 114 to the package substrate 122 to enable communication of the dies 114 with the PCB after the chip package 110 is mounted within the within the electronic device 100. Although not shown, it is contemplated that one or more additional IC dies may be stacked on one or both of the IC dies 114.

The electrical components of integrated chip package 110, such as the dies 114, communicate via traces formed on electrical interconnect components. The interconnect components having the traces can include one or more of the PCB 136, the packages substrate 112 and optional interposer 112, among others components. Careful construction of the traces as described below reduce the skin effect as compared to conventional traces utilized on conventional electrical interconnect components, thereby allowing the electronic device 100 having the integrated chip package 110 to perform more efficiently as compared to conventional designs.

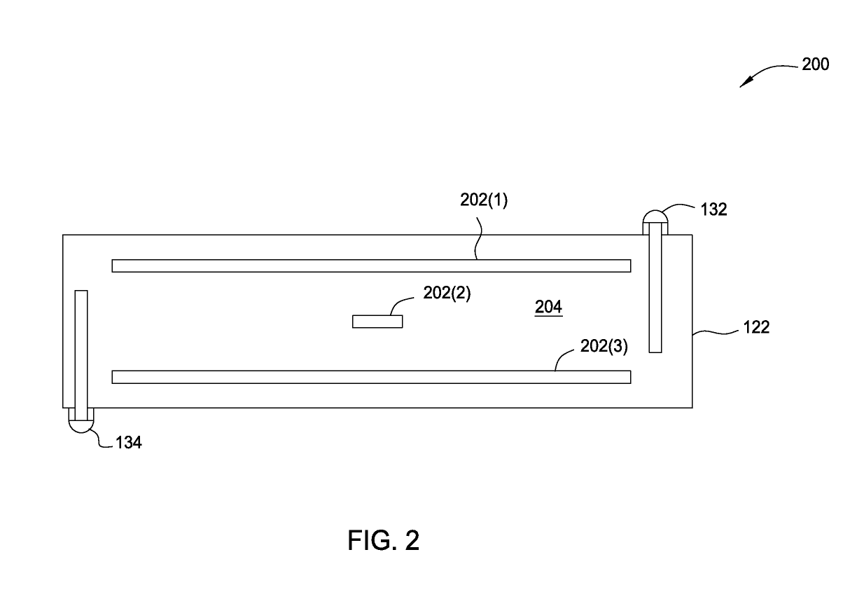

FIG. 2 is a partial cross-sectional view of the chip package 110 illustrated in FIG. 1, according to an embodiment. The cross-sectional view of the chip package 110 shows the package substrate 122 depicted in FIG. 1. The package substrate 122 includes conductors 202. The conductors 202 include a first reference plane 202(1), an electrical trace 202(2), and a second reference plane 202(3). The first reference plane 202(1) and the second reference plane 202(3) carry reference voltages and the trace 202(2) carries a data signal. Dielectric 204, included in the package substrate 122, electrically isolates the first reference plane 202(1), the electrical trace 202(2), and the second reference plane 202(3). Electrical trace 202(2) constitutes a stripline trace. The electrical trace at issue may constitute other types of traces other than a stripline trace, such as, without limitation, a microstrip trace, among others. Further, although shown as within the package substrate 122, the electrical trace may be included in other interconnect components within the system, such as the interposer 112 or the PCB 136, among others.

Electrical signals traveling through the conductors 202 are affected by an electrical phenomenon known as the skin effect. The skin effect is a phenomenon whereby an alternating current tends to flow predominantly through a skin region of a conductor as opposed to the central, interior region of the conductor. This effect is dependent on the frequency of the alternating current. A higher frequency current flows within a smaller, i.e., shallower, skin region. In other words, higher frequency signals flow through a relatively shallower region of a particular conductor as compared with lower frequency signals, which flow in a region extending comparatively deeper into the central, interior region of the conductor.

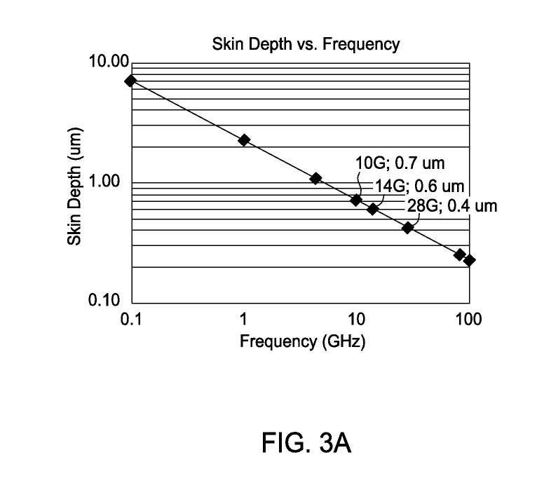

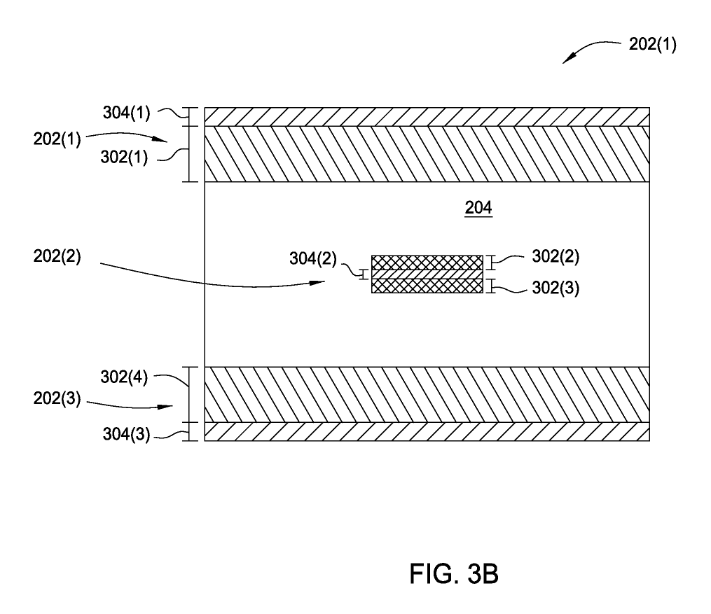

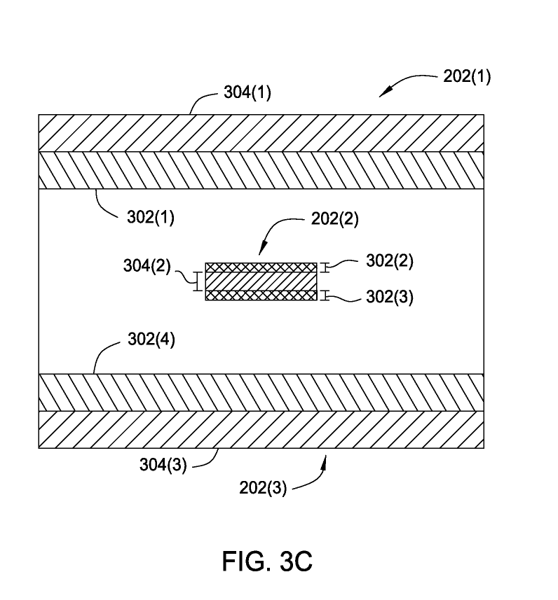

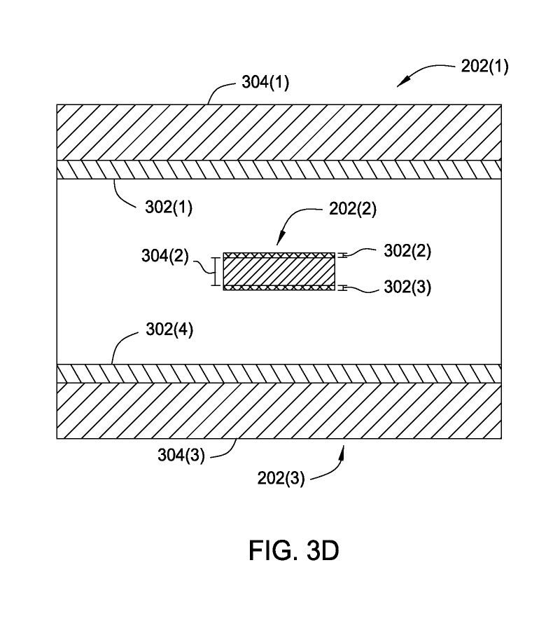

FIGS. 3A-3D are illustrations that demonstrate the skin effect. FIG. 3A is a graph that illustrates frequency in gigahertz (GHz) on the x-axis and skin depth in microns (μm) on the y-axis, with both frequency and depth provided on a logarithmic scale. As can be seen, as the frequency of the signal increases, the skin depth decreases. The skin depth represents the depth from the exterior surface of the electrical trace that electrical current at a particular frequency is restricted to flow. In other words, current at a particular frequency travels predominantly through only a region of the electrical trace defined from the exterior of the trace to the skin depth of the electrical trace, with substantially no current flow within the trace at depths deeper than the skin depth.

FIG. 3B is a cross-sectional illustration of the conductors 202 depicted in FIG. 2, further illustrating the skin effect for a particular signal frequency. More specifically, for the signal frequency associated with FIG. 3B, current predominantly flows through skin portions 302 of the conductors 202, with substantially no flow through the internal portions 304 of the conductors 202.

FIG. 3C is another cross-sectional illustration of the conductors 202 depicted in FIG. 2, further illustrating the skin effect for another signal frequency. The signal frequency associated with FIG. 3C is higher than the signal frequency associated with FIG. 3B, and therefore the skin depth is smaller than with FIG. 3B. Thus, the skin portions 302 illustrated in FIG. 3C are narrower than the skin portions 302 illustrated in FIG. 3B. FIG. 3D is a further cross-sectional illustration of the conductors 202 depicted in FIG. 2. The signal frequency associated with FIG. 3D is higher than the signal frequency associated with FIG. 3C, and therefore the skin depth is smaller than with FIG. 3C.

Because the skin effect restricts the current flow of a signal at a particular frequency to an area of a conductor consistent with the skin depth for that particular frequency, the resistance experienced by the signal at the particular frequency increases as the frequency increases. More specifically, resistance is defined as follows:

R=μL/A

where ρ is the resistivity, L is the length of the conductor, and A is the cross-sectional area of the conduct. As the skin depth decreases, the effective area through which current flows is reduced, and thus the resistance increases.

Additionally, the phase delay of signal at a particular frequency is also affected by the skin depth. More specifically, the phase delay t is proportional to the square root of LC, where L=Lᵢₙₜ Lₑₓₜ, and C is capacitance. Lᵢₙₜ is the internal inductance and Lₑₓₜ is the external inductance. As the skin depth decreases and current flows in an increasingly smaller region, internal inductance increases. Thus, as the frequency increases and skin depth decreases, the phase delay t increases.

In general, any particular signal transmitted via electrical devices such as the electronic device 100 described above has a frequency spectrum that includes a fundamental frequency and harmonic frequencies, as is generally known to those of skill in the art. Each frequency component of a signal is affected by the skin effect to a different degree. In other words, a low frequency component of a frequency spectrum for a particular signal has an associated skin depth that is greater than a skin depth associated with a higher frequency component of the particular signal. Because different frequencies are present in any given signal, those different frequencies are affected by the increased resistance and increased phase delays differently.

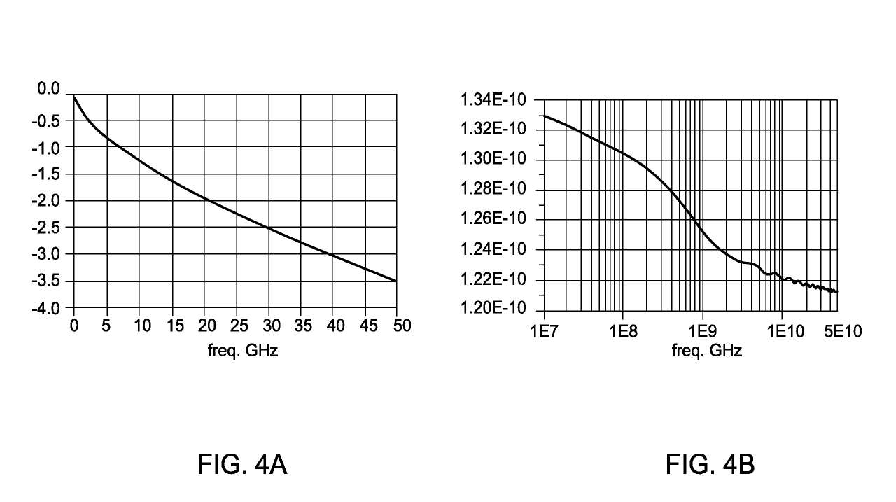

FIGS. 4A and 4B are graphs that illustrate the effects on attenuation (FIG. 4A) and phase delay (FIG. 4B) caused by the skin effect. FIG. 4A is a graph that plots frequency in gigahertz (GHz) on the x-axis versus attenuation in decibels (db) on the y-axis. The data depicted in FIG. 4A are example data for an example trace construction having a thickness of 15 μm and a width of 25 μm. As can be seen, attenuation of the signal is greater with higher signal frequencies. This attenuation limits the amount of information that can be transmitted in the signal, a measure commonly known as bandwidth. The 1.5-db bandwidth in FIG. 4A, which is the range of frequencies that spans 1.5 db of attenuation, is approximately 13 GHz. A flatter attenuation curve would allow for a greater bandwidth, as the signal would drop off by 1.5 db at a slower pace, thus allowing the 1.5 db of attenuation to span a greater spectrum of frequencies.

FIG. 4B is a graph that plots frequency in gigahertz (GHz) on the x-axis versus phase delay in seconds on the y-axis, with the y-axis labeled on the scale of 1 e⁻¹⁰ seconds (hundreds of picoseconds). As with FIG. 4A, the data depicted in FIG. 4B are example data for an example trace construction having a thickness of 15 μm and a width of 25 μm. As can be seen, the phase delay is higher at higher signal frequencies. The fact that phase delay increases with higher frequencies tends to cause frequency components of a particular signal to “smear” across a particular time period—a phenomenon known as signal dispersion. Dispersion tends to degrade the signal, which, as with the frequency-dependent attenuation described above, reduces the amount of information that can be derived from the signal. A flatter dispersion curve would allow for less dispersion, thus improving the signal quality.

In order to improve signal quality by increasing bandwidth and reducing dispersion, an electrical trace having a thickness that is based on characteristic skin depth is provided herein. The characteristic skin depth is based on a desired or “characteristic” data rate of the electronic device in which the electrical trace is located. The “characteristic” data rate is the intended data rate of signals that flow through the electrical trace. A characteristic data rate may be associated with any portion of an electrical device (e.g., a single trace, a group of traces, the entire device). For an electrical device having a higher characteristic data rate, the thickness of the electrical trace is lower than an electrical device having a lower characteristic data rate.

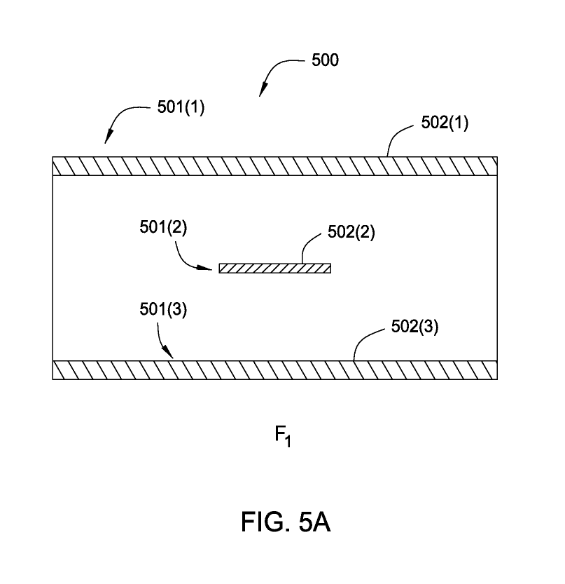

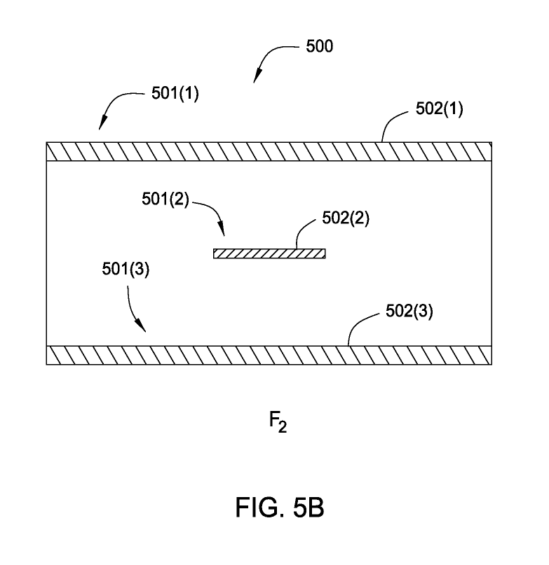

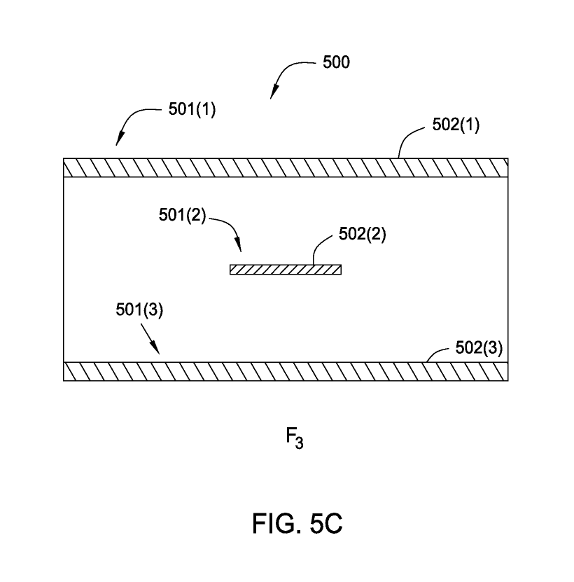

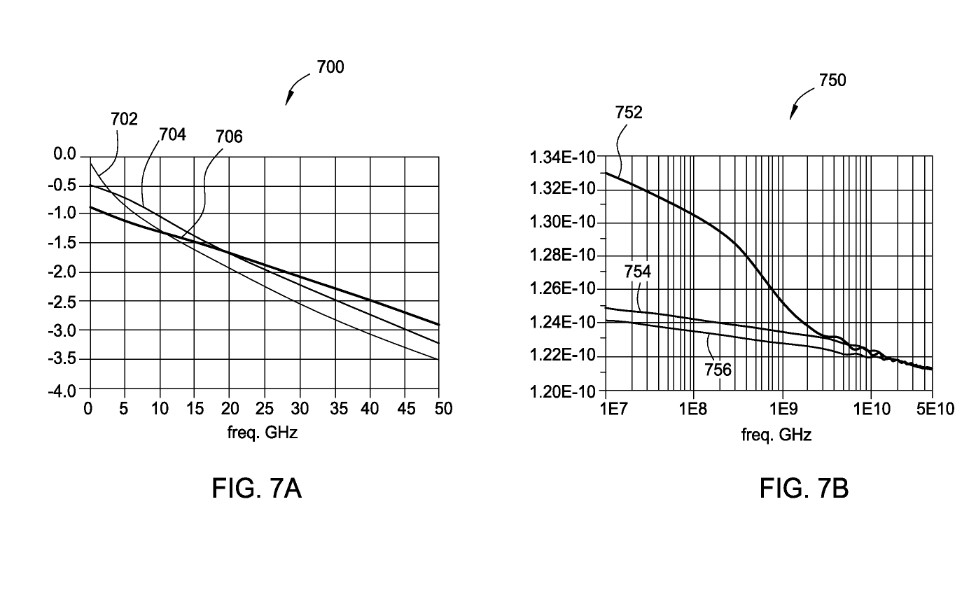

FIGS. 5A-5C are cross-sectional illustrations of conductors 501 having a construction for suppressing the skin effect. The conductors 501 are similar to the conductors 202 illustrated in FIGS. 2 and 3, but have differing dimensions. More specifically, the conductors 501 illustrated in FIGS. 5A-5C have a thickness that is less than a “skin depth” 502. The “skin depth” 502 is the portion of the conductors 501 through which current at a particular frequency of interest, as well as frequencies below that frequency, flows. By limiting the thickness of the conductors 501 in such a manner, the signal attenuation due to the skin effect is reduced or substantially eliminated, for the frequencies below and up to the frequency of interest. Although frequency components below the frequency of interest may be attenuated to a greater degree than those frequency components would be with a thicker electrical trace, the “attenuation curve” for the electrical trace becomes more flattened. Thus, bandwidth for the electrical trace increases, as demonstrated with respect to FIG. 7A. The construction of electrical trace described above also makes the “phase delay curve” more flattened, which reduces signal dispersion, as demonstrated with respect to FIG. 7B.

FIGS. 5A-5C illustrate the reduction in attenuation related to the skin effect. More specifically, FIG. 5A illustrates the skin depth 502 at a first frequency F₁. FIG. 5B illustrates the skin depth 502 at a second frequency F₂, which is greater than the frequency F₁, and FIG. 5C illustrates the skin depth 502 at a third frequency F3, which is greater than F₂. At all three frequencies, the current associated with those frequencies occupies substantially the entire cross-sectional area of the trace 501, and is thus attenuated to approximately the same degree.

In various embodiments, the “frequency of interest” (i.e., the frequency for which the related skin depth is calculated) is dependent on various characteristics. In one embodiment, the frequency is the highest frequency of system response that supports distortionless transmission of an incoming signal. In some embodiments, such a frequency is approximately equivalent to 0.35/RT, where RT is the rise time for the signal. In another embodiment, the frequency is below this frequency, and thus the skin depth does not penetrate the entire trace at all frequencies that are transmitted for a particular data rate.

As described above, the highest frequency of system response is based on the data rate intended for the electrical trace. More specifically, every data rate is associated with a minimum signal frequency for transmitting data at that data rate. The Nyquist theorem states that this signal frequency is one half of the data rate. Thus, a signal frequency of 28 gigahertz (GHz) is associated with a data rate of 56 gigabits per second (Gbps).

In some embodiments, the skin depth for the electrical trace is calculated as the skin depth associated with a frequency equivalent to one half of the data rate as described above. With such an electrical trace, frequency components of a signal up to the described frequency would flow through the entire cross-sectional area of the electrical trace, as the trace thickness would be less than the skin depth for all such frequencies. Thus, frequency-dependent signal attenuation would be generally unaffected by the skin effect up to that frequency.

In other embodiments, the skin depth is not calculated for the minimum frequency for supporting the particular data rate, but is calculated for a frequency substantially below that frequency. With the skin depth calculated for such a frequency, many, but not all, frequency components of a signal, up to the minimum frequency for supporting a particular data rate, are considered as being unaffected by the skin effect. Higher frequencies closer to this minimum frequency are, in fact, affected by the skin effect and thus are affected by some amount of frequency-dependent attenuation. One benefit of calculating the skin depth for a frequency below this minimum frequency is that overall attenuation for spectral components below this minimum frequency is lower than if the skin depth were calculated for the minimum frequency. Thus, these embodiments provide a trade-off by allowing frequency-dependent attenuation at the higher frequencies, while reducing overall attenuation at lower frequencies.

The skin depth referred to above describes the portion of an electrical trace through which current flows. Thus, because typically, current flows through both top and bottom skin regions, the thickness of the electrical trace is two times the calculated skin depth.

In some embodiments, the trace may have specific dimensions based on a characteristic data rate. More specifically, for a characteristic data rate of 56 gigabits per second and below (56 Gbps), the trace should have a thickness of approximately 1 μm. For a characteristic data rate of 28 Gbps and below, the trace should have a thickness of approximately 2 μm. For a characteristic data rate of 10 Gbps and below, the trace should have a thickness of approximately 5 μm.

In some embodiments, trace thickness is determined with additional reference to trace surface roughness. More specifically, because surface roughness represents variation in thickness of the trace, the full extent of possible thicknesses, including surface roughness is taken into account. The thickness of the electrical trace, without taking into account roughness effects, is referred to herein as the “nominal thickness.” In some embodiments, the trace has a width that is chosen to create a particular characteristic impedance and a low reflection transmission line. In some embodiments, the thickness of the trace is substantially the same over the entire length of the trace.

Although described above as being within the package substrate 122, electrical traces having characteristics described herein may be within other interconnect components of an electrical device, such as the interposer 112, PCB 136 or other components of the electronic device 100. In further embodiments, wires within a wire bond package coupled to the electronic device 100 may have a diameter calculated to match the skin depth as described above. In yet other embodiments, other electrical traces or wires in other electrical devices may be fabricated with the techniques described above.

As described above, the electrical trace 501(2) illustrated in FIGS. 5A-5C is surrounded by reference planes 501(1) and 501(3). In some embodiments, the reference planes 501(1) and 501(3) are fabricated with a thickness that matches the skin depth. In other embodiments, these reference planes 501(1) and 501(3) do not have a thickness that matches the skin depth and thus do not have a thickness associated with a data rate as described above.

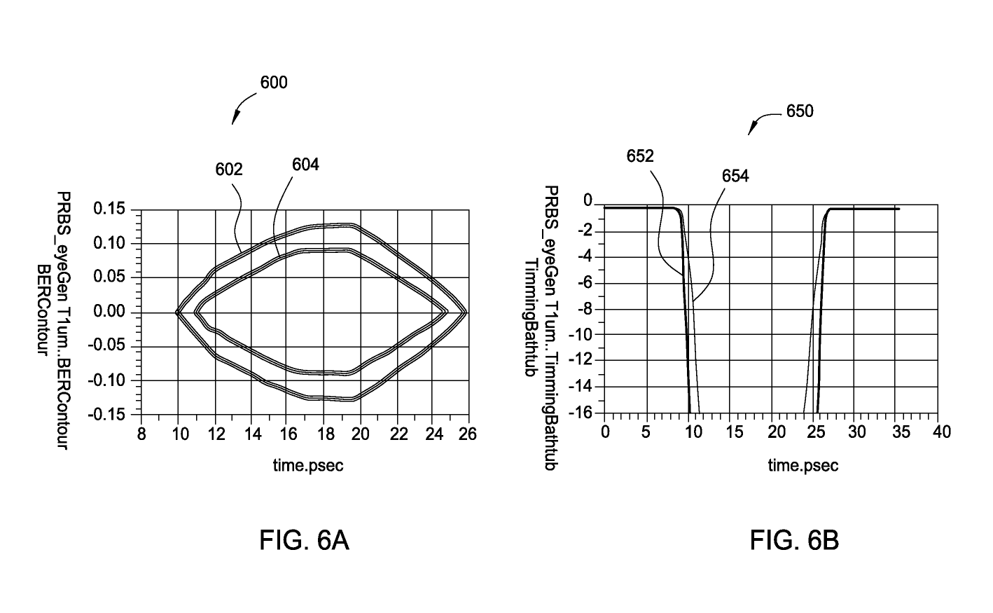

FIGS. 6A, 6B, 7A, 7B, 8A, and 8B illustrate some of the benefits of the above-described electrical trace construction. FIGS. 6A and 6B are graphs illustrating bit error rate of two different example trace constructions. Plots 602 and 652 are plots for an electrical trace having a thickness of 2 microns and plots 604 and 654 are plots for an electrical trace having a thickness of 15 microns. As can be seen, the bit error rate for the electrical trace having a thickness of 2 microns is 8 orders of magnitude less than the bit error rate for the electrical trace having a thickness of 15 microns.

FIG. 7A is a graph that charts frequency in GHz versus attenuation in decibels for three electrical traces having different thicknesses. A first graph 702 is for a trace having a thickness of 15 microns and a width of 25 microns. A second graph 704 is for a trace having a thickness of 2 microns and a width of 31 microns. A third graph 706 is for a trace having a thickness of 1 micron and a width of 32 microns. As shown in FIG. 7A, the 1.5-dB bandwidth for the first graph 702 is at 13 GHz. The 1.5-dB bandwidth for the second graph 704 is at 26 Ghz. The 1.5-dB bandwidth for the third graph 706 is at 40 GHz. As can be seen, an electrical trace having a smaller thickness has an improved bandwidth compared to thicker trances.

FIG. 7B is a graph that charts frequency in Hz versus phase delay in seconds for three electrical traces having different thicknesses. A first graph 752 is for a trace having a thickness of 15 microns and a width of 25 microns. A second graph 754 is for a trace having a thickness of 2 microns and a width of 31 microns. A third graph 756 is for a trace having a thickness of 1 micron and a width of 32 microns. Using the phase delay change over a 20 GHz range as the dispersion criteria, the first graph 752 is associated with a phase dispersion of 11.5 ps/20 GHz, the second graph 754 is associated with a phase dispersion of 3.5 ps/20 GHz, and the third graph 756 is associated with a phase dispersion of 2.5 ps/20 GHz. Thus, the phase delay is roughly five times flatter for a thinner electrical trace compared to thicker electrical traces.

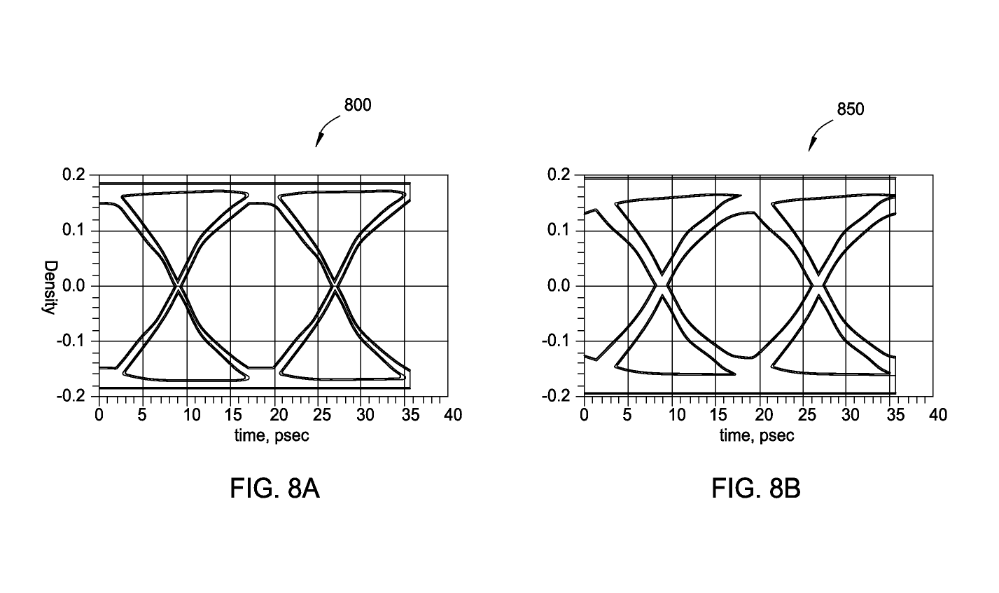

FIG. 8A is an eye diagram 800 illustrating data-dependent jitter for an electrical trace having a thickness of 1 micron. FIG. 8B is an eye diagram 850 illustrating data-dependent jitter for an electrical trace having a thickness of 15 microns. As can be seen by comparing FIGS. 8A and 8B, the peak-to-peak jitter is improved by two times for the 1 micron electrical trace as compared with the 15 micron trace.

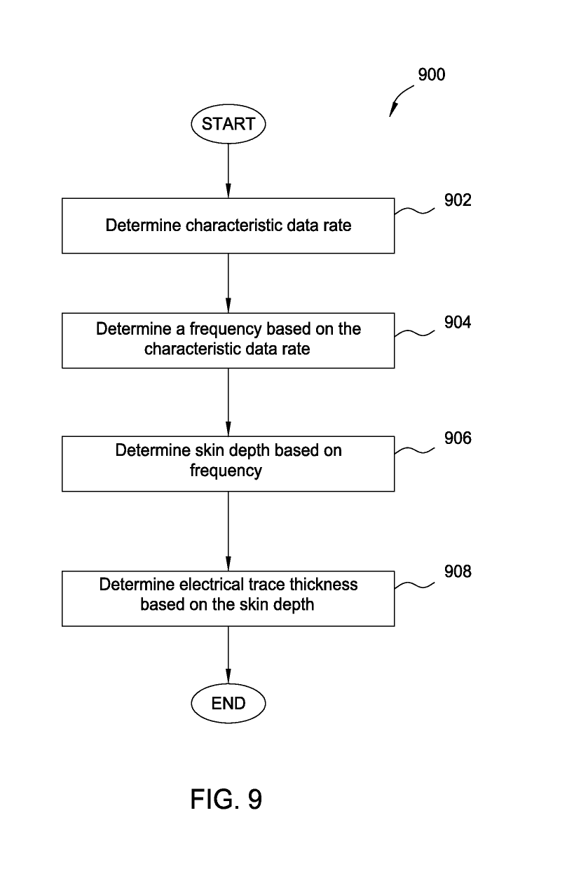

FIG. 9 is a flow diagram of method steps for determining geometrical characteristics for an electrical trace, according to an embodiment. The method 900 may be performed by, for example, an analytical design tool, such as a computing device configured to execute software for performing electrical analysis. The computing device may include, for example, a processor configured to execute instructions stored in a memory, or other types of hardware computing devices. The method 900 begins at step 902, in which the analytical design tool determines a characteristic data rate. The characteristic data rate is a data rate associated with a particular electrical device or electrical component in which the electrical is located. The characteristic data rate describes the highest rate at which the electrical trace is designed to transmit data. In step 904, the analytical design tool determines a frequency based on the characteristic data rate. In some embodiments, the frequency is the minimum frequency for transmitting data at the data rate, according to the Nyquist theorem. This frequency is one half of the characteristic data rate. In other embodiments, the frequency is significantly below this frequency. In step 906, the analytical design tool determines a skin depth based on the frequency. The skin depth may be calculated based on known methods. In step 908, the analytical design tool determines an electrical trace thickness based on the calculated skin depth. In some embodiments, the electrical trace thickness is twice the skin depth, since the skin depth defines the depth to which electrical current of a particular frequency substantially penetrates for any particular surface, and current typically flows through top and bottom surfaces of an electrical trace.

The electronic device including electrical trace of an interconnect component described above advantageously suppresses effects in the electrical trace that are related to the skin effect. The effects include frequency-dependent attenuation and frequency-dependent phase delay effects. The improvements described herein generally improve bandwidth, and reduces dispersion, jitter, and bit error.

While the foregoing is directed to embodiments of the present invention, other and further embodiments of the invention may be devised without departing from the basic scope thereof, and the scope thereof is determined by the claims that follow.

What we claim is:

1. An electrical interconnect component of an electronic device, the electronic device having a characteristic data rate, the electrical interconnect component comprising:
a dielectric surface; and
an electrical trace disposed on the dielectric surface, the electrical trace having a thickness selected in response to the characteristic data rate, the thickness selected independent of any relationship to a width of the electrical trace.

2. The electrical interconnect component of claim 1, wherein the width of the electrical trace is selected in response to a characteristic resistance associated with the electrical trace and on the thickness.

3. The electrical interconnect component of claim 1, wherein the thickness is less than two times a skin depth associated with a signal driven on the electrical trace at the characteristic data rate.

4. The electrical interconnect component of claim 1, wherein the thickness is measured from a peak surface roughness.

5. The electrical interconnect component of claim 1, wherein the thickness is approximately equal to two times a skin depth associated with a signal driven on the electrical trace at the characteristic data rate.

6. The electrical interconnect component of claim 5, wherein the characteristic data rate of the electronic device is at least 10 gigabits per second, and
the thickness of the electrical trace less than is about 5 microns.

7. The electrical interconnect component of claim 5, wherein the characteristic data rate of the electronic device is at least 28 gigabits per second; and
the thickness of the electrical trace is less than about 2 microns.

8. The electrical interconnect component of claim 5, wherein the characteristic data rate of the electronic device is at least 56 gigabits per second; and
the thickness of the electrical trace is less than about 1 micron.

9. The electrical interconnect component of claim 1, wherein the electrical trace comprises a stripline trace.

10. An electronic device having a characteristic data rate, the electronic device comprising:
an electrical component; and
an electrical interconnect component coupled to circuitry of the electrical component, the electrical interconnect component comprising:
a dielectric surface; and
an electrical trace disposed on the dielectric surface, the electrical trace having a thickness selected in response to the characteristic data rate, the thickness selected independent of any relationship to a width of the electrical trace.

11. The electronic device of claim 10, wherein the width of the electrical trace is selected in response to a characteristic resistance associated with the electrical trace and on the thickness.

12. The electronic device of claim 10, wherein the thickness is less than two times a skin depth associated with a signal driven on the electrical trace at the characteristic data rate.

13. The electronic device of claim 10, wherein the thickness is measured from a peak surface roughness.

14. The electronic device of claim 10, wherein the thickness is approximately equal to two times a skin depth associated with a signal driven on the electrical trace at the characteristic data rate.

15. The electronic device of claim 14, wherein the characteristic data rate of the electronic device is at least 10 gigabits per second, and
the thickness of the electrical trace less than is about 5 microns.

16. The electronic device of claim 14, wherein the characteristic data rate of the electronic device is at least 28 gigabits per second; and
the thickness of the electrical trace is less than about 2 microns.

17. The electronic device of claim 14, wherein the characteristic data rate of the electronic device is at least 56 gigabits per second; and
the thickness of the electrical trace is less than about 1 micron.

18. The electronic device of claim 10, wherein the electrical trace comprises a stripline trace.

19. A method of communicating via an electrical trace, comprising transmitting a signal having a characteristic data rate through the electrical trace that has a thickness selected in response to the characteristic data rate, the thickness selected independent of any relationship to a width of the electrical trace.

20. The method of claim 19, wherein width of the electrical trace is selected in response to a characteristic resistance associated with the electrical trace and on the thickness.
